(19) United States
(12) Patent Application Publication
(10) Pub. No.: US 2023/0065475 A1
(43) Pub. Date: Mar. 2, 2023

(54) PARTICLE BEAM SYSTEM WITH MULTI-SOURCE SYSTEM AND MULTI-BEAM PARTICLE MICROSCOPE

(71) Applicant: Carl Zeiss MultiSEM GmbH, Oberkochen (DE)

(72) Inventors: Dirk Zeidler, Oberkochen (DE); Hans Fritz, Grabs (CH); Ingo Mueller, Aalen (DE)

(21) Appl. No.: 17/983,220

(22) Filed: Nov. 8, 2022

Related U.S. Application Data
(63) Continuation of application No. PCT/EP2021/025182, filed on May 17, 2021.

(30) Foreign Application Priority Data
Jun. 8, 2020 (DE) 102020115183.7

(51) Int. Cl. H01J 37/09; H01J 37/28; H01J 37/21; H01J 37/14; H01J 37/147; H01J 37/153; H01J 37/073

(52) U.S. Cl. CPC H01J 37/09; H01J 37/28; H01J 37/21; H01J 37/14; H01J 37/1472; H01J 37/153; H01J 37/073; H01J 2237/0453; H01J 2237/0635; H01J 2237/0835; H01J 2237/1534

(57) ABSTRACT

A particle beam system includes a multi-source system. The multi-source system comprises an electron emitter array as a particle multi-source. The inhomogeneous emission characteristics of the various emitters in this multi-source system are correctable, or pre-correctable for subsequent particle-optical imaging, via particle-optical components that are producible via MEMS technology. A beam current of the individual particle beams is adjustable in the multi-source system.

### CROSS-REFERENCE TO RELATED APPLICATIONS

The present application is a continuation of, and claims benefit under 35 USC 120 to, international application PCT/EP2021/025182, filed May 17, 2021, which claims benefit under 35 USC 119 of German Application No. 10 2020 115 183.7, filed Jun. 8, 2020. The entire disclosure of these applications are incorporated by reference herein.

### FIELD

The disclosure relates to particle beam systems which operate with a multiplicity of particle beams.

### BACKGROUND

Just like single-beam particle microscopes, multi-beam particle microscopes can be used to analyse objects on a microscopic scale. Images of an object that represent a surface of the object, for example, can be recorded using these particle microscopes. In this way, for example the structure of the surface can be analysed. While in a single-beam particle microscope a single particle beam of charged particles, such as, for example, electrons, positrons, muons or ions, is used to analyse the object, in a multi-beam particle microscope, a plurality of particle beams are used for this purpose. The plurality of the particle beams, also referred to as a bundle, are directed at the surface of the object at the same time, as a result of which a significantly larger area of the surface of the object can be sampled and analysed as compared with a single-beam particle microscope within the same period of time.

WO 2005/024881 A2 discloses a multiple particle beam system in the form of an electron microscopy system which operates with a multiplicity of electron beams in order to scan an object to be examined using a bundle of electron beams in parallel. The bundle of electron beams is generated by an electron beam generated by an electron source being directed at a multi-aperture plate having a multiplicity of openings. One portion of the electrons of the electron beam strikes the multi-aperture plate and is absorbed there, and another portion of the beam passes through the openings in the multi-aperture plate, and so an electron beam is shaped in the beam path downstream of each opening, the cross section of the electron beam being defined by the cross section of the opening. Furthermore, suitably chosen electric fields provided in the beam path upstream and/or downstream of the multi-aperture plate have the effect that each opening in the multi-aperture plate acts as a lens on the electron beam passing through the opening, and so the electron beams are focused in a plane situated at a distance from the multi-aperture plate. The plane in which the foci of the electron beams are formed is imaged by a downstream optical unit onto the surface of the object to be examined, such that the individual electron beams strike the object in a focused manner as primary beams. There they generate interaction products, such as backscattered electrons or secondary electrons, emanating from the object, which are shaped to form secondary beams and are directed at a detector by a further optical unit. There each of the secondary beams strikes a separate detector element such that the electron intensities detected by the detector element provide information relating to the object at the location at which the corresponding primary beam strikes the object. The bundle of primary beams is scanned systematically over the surface of the object in order to generate an electron micrograph of the object in the manner that is customary for scanning electron microscopes.

In the multiple particle beam system described, a high resolution and a high throughput can be highly relevant for the satisfactory and successful use in practice. In this context, it can be desirable, inter alia, to set the intensity of the particle beams.

US 2017/0025241 A1 discloses a multi-beam particle beam system, in which the current density within the particle beams is variable. Specifically, the irradiance is set herein, before multi-beams are even formed from the primary electron beam. To set the irradiance, a double collimator is used as per US 2017/0025241 A1, the double collimator being arranged directly downstream of the electron source in the beam direction. By varying the lens excitation of the double collimator, it is possible to vary the current density of the electrons which pass the openings in a multi-aperture plate downstream of the double collimator.

However, it is possible for the above-described multi-beam particle beam system to reach its limits if the number of utilized particle beams is increased further. In order even to obtain sufficient beam currents for the individual beams, it is desirable to use as many particles from the particle source as possible. However, in that case the emission characteristic of the particle source can become more relevant, more precisely the uniformity of the emission characteristic over the entire utilized emission angle. When using relatively large emission angles, the emission characteristic of particle sources, e.g., of thermal field emission (TFE) sources, may no be longer uniform throughout. Accordingly, the irradiance at a multi-aperture plate in a corresponding particle beam system may no longer uniform throughout and there are relatively large variations in the current densities in different individual beams. However, in the case of multi-particle inspection systems, it is generally desirable for the system to exhibit only a small variation in the current strengths between the various individual beams, which is typically less than a few percent, so that all individual image fields of the multi-image field are scanned with an equivalent number of particles or electrons per pixel. By way of example, this can be a precondition to obtain individual images with approximately the same brightness.

Thus, the use of particle sources with large emission angles and, at the same time, significant demands on the current per individual beam can represent a challenge in the case of inspection systems operating with multi-beam particle beam systems on account of the varying emission characteristic.

There also already are multi-beam particle beam systems that operate using multi-sources. This approach also increases the number of individual particle beams available for the multi-beam particle beam system. In principle, photocathodes and cold field emitter arrays (cold FEAs) are known as multi-sources. However, photocathodes can have an unstable emission characteristic, a short service life and a low brightness. By contrast, cold field emitter arrays can have a comparatively high brightness and a small virtual source size. They can also be produced via methods that are conventional in microstructure technology, e.g., the combination of lithography methods and subsequent etching and/or deposition methods (MEMS technology; microelectromechanical systems technology). However, in general, the emission characteristic of cold field emitter arrays is not uniform and it can be challenging to produce the individual tips for the emission with reproducible characteristics and specifications, for example, in view of their emission characteristic, in view of their overall current and in view of their virtual source diameter.

US 2014/0057212 A1 discloses a lithography system which operates with a multiplicity of individual particle beams. It does not comprise a multi-source but a single source.

US 2016/0111251 A1 discloses a multi-beam electron microscope which likewise operates with a single source and not with a multi-source. Moreover, different options for field curvature correction are disclosed.

DE 10 2014 008 083 A1 discloses a particle beam system with a single source. Various arrangements of multi-aperture plates for beam shaping are disclosed, for example field generators for generating multi-pole fields are disclosed.

US 2012/0295203 A1 discloses a lithography system which operates with a single source. A two-stage system with successive individual lenses used to set the relative position of a cross over is disclosed in the region close to the source.

US 2014/0042334 A1 discloses a lithography system with a single source.

U.S. Pat. No. 8,618,496 B2 discloses various field generators for manipulating individual particle beams. No multi-source system is disclosed.

WO 2007/028595 A2 discloses a particle beam system with a single source. Various multi-aperture plate arrangements are disclosed, with use also being made of plates with curved surfaces and hence varying distances to one another.

US 2013/0344700 A1 discloses a further lithography system which operates with a single source.

U.S. Pat. No. 8,384,051 B2 discloses a further lithography system which operates with a single source. The cited document focuses on questions relating to detection.

WO 2005/024881 A2 discloses a multiple particle beam system which operates with a single source. Arrangements of multi-aperture plates are disclosed, and aspects of image field effect correction are discussed.

### SUMMARY

The present disclosure seeks to provide a particle beam system that operates with a multiplicity of individual beams, wherein the particle beam system can help ensure relatively good beam uniformity of the individual beams, even if use is made of a large number of individual beams and, at the same time, can help ensure a relatively high beam current for each individual beam. The particle beam system can be suitable for multi-beam inspection systems.

The disclosure seeks to increase the throughput in a particle beam system.

The disclosure seeks to improve the usability of multi-sources for multi-beam particle beam systems.

The disclosure seeks to reduce imaging aberrations of the particle beam system to the greatest possible extent.

Here, the disclosure involves the following consideration: It is possible to use existing particle multi-sources which produce electrons by cold field emission for particle beam systems with a high resolution and high throughput if the inhomogeneities in the beam current density of the individual particle beams due to the multi-source are compensated for or removed before the actual particle-optical imaging takes place. According to the disclosure, it is therefore proposed to initially coarsely shape the individual particle beams close to the multi-source, wherein MEMS technology can be used for the production of the lenses, deflectors, stigmators, etc. used in the process. The actual final beam shaping, in which the individual particle beams are formed for high-resolution particle-optical imaging, is implemented later within the particle beam system. Near the multi-source, the energy of the individual particle beams still is comparatively low and the individual particle beams can be influenced or deflected using comparatively low voltages or currents. In turn, low voltages or currents are good preconditions for a low-risk design of MEMS apparatuses, in which comparatively high demands may be placed on the insulation of conductor tracks situated thereon.

Moreover, as a result of this two-stage shaping of the individual particle beams, it is already possible to pre-thin the individual particle beams originally emitted by the multi-source close to the source thereof; this reduces the Coulomb effect, which is generally disadvantageous in view of a high resolution.

Specifically, according to a first aspect, the disclosure relates to a particle beam system comprising the following:

a multi-source system comprising
a particle multi-source, for example an electron emitter array, which is set up to generate a multiplicity of charged individual particle beams by field emission, for example cold field emission;
a first multi-aperture plate with a multiplicity of first openings, the individual particle beams at least partly passing therethrough;
a first multi-lens array which comprises a multiplicity of individually adjustable particle lenses and which is arranged in the beam path downstream of the first multi-aperture plate in such a way that the individual particle beams which pass through the first multi-aperture plate also pass through the first multi-lens array;
a second multi-aperture plate with a multiplicity of second openings, which is arranged in the beam path downstream of the first multi-lens array in such a way that the individual particle beams which pass through the first multi-lens array also pass through the second multi-aperture plate; and
a beam current-restricting multi-aperture plate with a multiplicity of beam current-restricting openings, which is arranged in the beam path downstream of the second multi-aperture plate in such a way that the individual particle beams are partly incident on the beam current-restricting multi-aperture plate and absorbed there and partly pass through the openings in the beam current-restricting multi-aperture plate; and
a controller which is set up to supply an individually adjustable excitation to the particle lenses of the first multi-lens array and thus individually set the focusing of the associated particle lens for each individual particle beam.

Thus, in this case, the particle multi-source of the multi-source system produces electrons or emits electron beams. The particle multi-source can be embodied as an electron emitter array in this case, in which the individual emitters or tips are arranged in a regular pattern. By way of example, they can be arranged in a chequerboard-like fashion or in a hexagonal pattern. By way of example, such an electron emitter array can be manufactured using MEMS technology, wherein, e.g., lithography methods are combined with subsequent etching and/or deposition methods. By way of example, metallic emitters, silicon-based emitters and/or carbon nano tube-based emitters are suitable for the emitters of the electron emitter arrays. The particle multi-source comprises a multiplicity of true particle sources; for example, it can have a multiplicity of tips.

In the multi-source system, the first multi-aperture plate, the first multi-lens array and the second multi-aperture plate are arranged in this order in the beam path downstream of the particle multi-source. Here, in terms of this patent application, a distinction is made throughout between multi-aperture plates on the one hand and multi-lens arrays on the other hand. A multi-aperture plate is a plate with a multiplicity of openings. Here, a voltage could be applied to this multi-aperture plate overall. This could but need not be the case. In any case, all openings in a multi-aperture plate have a uniform, globally identical electric potential. By contrast, a multi-lens array in terms of this patent application is—in comparison with a multi-aperture plate—a more complex component: In terms of this patent application, a multi-lens array comprises a multiplicity of lenses arranged substantially parallel to one another, which are each adjustable individually and independently of one another such that the individual lenses of the multi-lens array can have different refractive powers from one another and these refractive powers can be varied, independently of one another, on an individual basis for each lens.

A multi-lens array comprises the following according to an embodiment:
a lens multi-aperture plate with a multiplicity of openings; and
a multiplicity of electrodes which are arranged around the multiplicity of openings in the lens multi-aperture plate in order to individually influence the individual particle beam passing through the respective opening.

By way of example, the electrodes can be ring electrodes; however, other embodiment are also possible. By way of example, it is possible to apply the same voltage to all electrodes in the case of azimuthally divided electrodes, such as, e.g., a quadrupole or octupole. Further, it is possible to bring about the focusing effect by coils which enclose each opening in the lens multi-aperture plate in a plane perpendicular to the beam direction. For deflecting coils, this is described in DE 10 2014 008 083 B4.

The openings in the first multi-aperture plate, in the second multi-aperture plate and in the first multi-lens array are circular in each case and, overall, the individual openings can be arranged in a hexagonal structure; however, other arrangement options are also possible. It is possible to match the number of openings in the first multi-aperture plate, in the second multi-aperture plate, and in the first multi-lens array to the number of individual particle beams or to the number of emitters or tips of the particle multi-source. In this case, it is desirable for the number of individual particle beams formed is 3n (n−1)+1, where n is any natural number, in the case of a hexagonal arrangement. However, alternatively, it is also possible for a plurality of individual particle beams to be formed from one emitter. By way of example, this can be achieved by virtue of the first multi-aperture plate having more openings, to be precise m openings per emitter. However, in that case it is desirable again for the number of openings in the first multi-aperture plate, in the second multi-aperture plate and in the first multi-lens array are identical to one another in each case. Moreover, the openings should be arranged centred above one another in the beam path of the individual particle beams. Here, it is desirable for the diameter of the openings in the first multi-aperture plate is smaller than the diameter of the openings in the first multi-lens array and in the second multi-aperture plate. Unlike in the case of the first multi-lens array and the second multi-aperture plate, the individual particle beams at least partly pass through the first multi-aperture plate; i.e., the first multi-aperture plate can also block electrons emitted by the emitters.

A sequence of openings in the first multi-aperture plate, in the first multi-lens array and in the second multi-aperture plate forms an individual lens. In this case, a substantially identical first voltage U₁, which may also be zero, is applied to the first multi-aperture plate and to the second multi-aperture plate. By contrast, the individually adjustable voltages U₂+Vᵢ at the first multi-lens array substantially differ from the first voltage U₁. In this case, the notation Vᵢ expresses that the adjustable voltages vary around the value U₂, i.e., U₂ is a mean value or reference value.

Depending on the excitation of the individually adjustable particle lenses, the sequence of openings in the first multi-aperture plate, in the first multi-lens array and in the second multi-aperture plate has a different focusing effect. Thus, after passing through the individual lenses, the individual particle beams have different divergences and are then expanded to a different extent following a short travel along a drift path. These individual particle beams which have been expanded to a different extent subsequently are incident on the beam current-restricting multi-aperture plate with a multiplicity of beam current-restricting openings. Some particles of the individual particle beams strike the beam current-restricting multi-aperture plate and are absorbed there and some of these pass through the openings in the beam current-restricting multi-aperture plate. This allows the beam current strength to be set individually for each individual particle beam within the multi-source system. Therefore, it is possible, for example, to compensate for different emission characteristics or current strengths of the individual sources or tips by way of this adjustment process. In this way, conventional particle multi-sources on electron emitter array basis can consequently also be rendered usable for high-resolution particle beam systems. The final beam shaping of the individual particle beams for the actual particle-optical imaging is only implemented later in the particle beam system. The following relationship can apply to deviations δ of the individual beam currents from an arithmetic mean of the beam currents immediately after the beam current-restricting multi-aperture plate has been passed through: δ≤5%, such as δ≤2%, for example δ≤1%.

The controller which is set up to supply an individually adjustable excitation to the particle lenses of the first multi-lens array and thus individually adjust the focusing of the associated particle lens for each individual particle beam can be identical to the controller for the entire particle beam system. However, this need not be the case. The adjustable excitations are voltages and/or currents, for example.

The openings in the beam current-restricting multi-aperture plate can in turn be aligned centrally with respect to the openings in the first multi-aperture plate, in the first multi-lens array and in the second multi-aperture plate. The diameter of the beam current-restricting openings is smaller than the diameter of the openings in the second multi-aperture plate and in the first multi-lens array.

The second multi-aperture plate and the beam current-restricting multi-aperture plate can also be functionally combined or brought together with one another. Thus, the second multi-aperture plate and the beam current-restricting multi-aperture plate are not necessarily two separate component parts. However, structural separation has desirable electron-optical properties.

According to an embodiment of the disclosure, the particle beam system furthermore comprises the following: a final beam-shaping system, which is arranged in the beam path downstream of the multi-source system and via which the individual particle beams are provided with a shape for subsequent particle-optical imaging. The term “final beam-shaping” in this case indicates that the individual particle beams that are ultimately used for the actually relevant particle-optical imaging are formed via the final beam-shaping system. Parameters such as homogeneous individual particle beam current density, rotation, telecentricity, astigmatism (to be removed), etc., are taken into account or set for the subsequent particle-optical imaging within the scope of the final beam shaping. On account of the settings undertaken, particle-optical imaging with a high resolution and a high throughput is possible. Individual structural constituent parts of the final beam-shaping system will still be discussed in more detail below within the scope of this patent application.

According to an embodiment of the disclosure, the first multi-aperture plate is embodied as an extractor electrode; and/or the second multi-aperture plate is embodied as a counter electrode; and/or the (final) beam current-restricting multi-aperture plate is embodied as an anode. This embodiment is based on the fact that existing particle multi-sources which generate a multiplicity of charged individual particle beams by field emission in any case have various electrodes in the form of perforated plates. In this case, an identical voltage can be applied to the extractor electrode and to the counter electrode. The same voltage as applied to the extractor electrode and/or the counter electrode, or a different voltage, can likewise be applied to the anode.

According to an embodiment of the disclosure, the following relationship applies to a distance A between the particle multi-source and the beam current-restricting multi-aperture plate: 0.1 mm≤A≤30 mm, such as 0.1 mm≤A≤20 mm, for example 0.1 mm≤A≤10 mm. Thus, the beam current-restricting multi-aperture plate is arranged very close to the particle multi-source. In this case, the distance A is measured from the tip of the particle emitter to the surface of the beam current-restricting multi-aperture plate that faces the particle multi-source. Accordingly, a thickness of the multi-source system in the direction of the optical axis Z of the particle beam system is less than 30 mm, such as less than 20 mm, for example less than 10 mm. In this case, the multi-source system can still have further constituent parts, which contribute to the overall thickness or the overall extent of the multi-source system.

According to a further embodiment of the disclosure, the multi-source system furthermore comprises a suppressor electrode. A voltage is applied to this electrode in such a way that it presses the electrons out of the source region of the particle multi-source.

According to a further embodiment of the disclosure, the multi-source system comprises a second multi-lens array, wherein the second multi-lens array comprises a multiplicity of individually adjustable and focusing particle lenses and is arranged in the beam path downstream of the beam current-restricting multi-aperture plate in such a way that the particles of the individual particle beams which pass through the beam current-restricting multi-aperture plate substantially also pass through the second multi-lens array. Furthermore, the controller is set up to supply an individually adjustable excitation to the particle lenses of the second multi-lens array and thus individually set the focusing of the associated particle lens for each individual particle beam. For example, the first and the second multi-lens array can have the same design, which simplifies the manufacturing of the particle beam system. However, the first and the second multi-lens array can also have different configurations. Furthermore, the statements already made in respect of the first multi-lens array apply to the second multi-lens array. As a result of the individually adjustable excitations, the second multi-lens array can individually set the focal lengths for the respective individual particle beams. When passing through the first multi-lens array, the focal length for the individual particle beams has changed slightly on account of the different lens excitations for the individual particle beams. These deviations can now be corrected by way of the provision of the second multi-lens array. It is also possible with the aid of the second multi-lens array to undertake field curvature correction for the subsequent particle-optical imaging. This is because should the subsequent field curvature—caused by the subsequent particle-optical imaging—be known, it can be compensated by an appropriate excitation of the particle lenses of the second multi-lens array.

According to an embodiment of the disclosure, the multi-source system furthermore comprises a first multi-deflector array, through which the individual particle beams pass and which is arranged in the beam path downstream of the beam current-restricting multi-aperture plate. Here, the controller is furthermore set up to supply individually adjustable excitations to the first multi-deflector array and thus individually deflect the individual particle beams. In this case, the multi-deflector array serves as direction correction for the individual particle beams, for example. A possibly present beam migration, which may arise, for example, due to openings in the multi-aperture plate that, on account of manufacturing tolerances, are not aligned, can be compensated for. The structure of multi-deflector arrays is known as a matter of principle (see, e.g., DE 10 2014 008 083 B9); this can relate to electrostatic deflection fields in openings in the multi-deflector array. In this case, provision can be made, e.g., of electrodes that are subdivided in the azimuthal direction and are driveable in pairs for an appropriate direction correction.

According to an embodiment of the disclosure, the multi-source system furthermore comprises a multi-stigmator array, through which the individual particle beams pass. In this case, the controller is furthermore set up to supply an adjustable excitation to the multi-stigmator array. The stigmators of the multi-stigmator array provide multi-pole fields which depend on the excitation of the stigmators and which can be used to alter locations and angles at which the individual particle beams are incident on an object to be examined. However, it is also possible to influence the astigmatism per individual particle beam. Imaging aberrations of the particle-optical imaging can be corrected.

According to an embodiment of the disclosure, the multi-source system is manufactured at least in part via MEMS technology. It is also possible that all components of the multi-source system have been manufactured via MEMS technology.

According to an embodiment of the disclosure, the particle multi-source has at least one of the following emitter types: metallic emitters, silicon-based emitters, carbon nanotubes-based emitters.

According to an embodiment of the disclosure, the particle beam system furthermore comprises a magnetic field generation mechanism, which is arranged in such a way that the particle multi-source is arranged in a magnetic field. For example, the emitter plane, in which the tips of the multi-source are situated, is arranged within a magnetic field in this case. The charged particles or electrons thus start within a magnetic field into the particle beam system; as it were, they are born within the magnetic field. A targeted arrangement of the magnetic field relative to the emitter plane renders it possible to impress a defined start angle distribution onto the electrons. Thus, their start velocity vector projected onto the emitter plane has a certain direction, specifically orthogonal to the respectively applied magnetic field. This embodiment offers an opportunity of correcting landing angles in the object plane or on the sample. In principle, aberrations occurring in the object plane are proportional to the image-side focal length. To obtain a short focal length of the objective lens, which leads to smaller aberrations, work can be carried out with magnetic immersion. However, this leads to the object plane still being located within the magnetic field. Individual particle beams incident on the object plane or the object experience Larmor rotation on account thereof, the latter being, e.g., proportional to the radius R or to the distance from the optical axis Z. The individual particle beams therefore have angular momentum in respect of the optical axis Z. This angular momentum can be compensated for at the source by the provision of an appropriately formed magnetic field. This facilitates telecentric landing of the individual particle beams in the object plane. This is desirable, for example, when examining so-called HAR structures (high aspect ratio structures), in which the ratio of width to depth can be approximately 1:100 or more.

According to an embodiment of the disclosure, the magnetic field generated by the magnetic field generation mechanism has a component perpendicular and/or a component parallel to the emission direction of the charged particles from the multi-source. In this case, the perpendicular component ensures a deflection or the impression of generalized angular momentum on the electrons in the magnetic field.

According to an embodiment, the magnetic field generation mechanism is embodied in such a way that the start angular distribution of the charged particles caused by the magnetic field following the emergence of the charged particles from the particle source depends on the radial distance of the respective particle source to the optical axis of the particle beam system. This can facilitate a correction of the arising Larmor rotation within the object plane, which is proportional to the distance r of the point of incidence from the optical axis Z.

In this case, the magnetic field generation mechanism can have an integral or multipart embodiment. By way of example, they can comprise pole pieces in which coils are arranged in suitable fashion. In this case, it is desirable to arrange the magnetic field generation mechanism on the side of the particle beam system distant from the beam path, for example above the particle multi-source or above the entire multi-source system.

According to an embodiment of the disclosure, the particle beam system furthermore comprises the following:
a condenser lens system, which is arranged downstream of the multi-source system and upstream of the final beam-shaping system in the direction of the beam path;
a field lens system, which is arranged downstream of the final beam-shaping system in the direction of the beam path; and
an objective lens system, which is arranged downstream of the field lens system in the direction of the beam path,

wherein an intermediate image plane is formed between the final beam-shaping system and the field lens system.

The final beam-shaping system is arranged in the beam path—as already explained above—downstream of the multi-source system and serves to shape the individual particle beams for the subsequent particle-optical imaging. In this case, shaping the individual particle beams via the final beam-shaping system is carried out at comparatively high energies of the individual particle beams and hence with high precision. This precision is also decisive for the quality of the subsequent particle-optical imaging of the intermediate image plane onto the object plane. In this case, the images of the multi-sources are located in the intermediate image plane; they can therefore be considered to be virtual particle sources for the subsequent imaging from the intermediate image plane into the object plane.

According to an embodiment, the final beam-shaping system comprises the following:
a final multi-aperture plate with a multiplicity of openings, which is arranged in such a way that the individual particle beams are partly incident on the final multi-aperture plate and absorbed there and partly pass through the openings in the final multi-aperture plate, and
a third multi-lens array which comprises a multiplicity of adjustable particle lenses and which is arranged in the beam path downstream of the final multi-aperture plate in such a way that the individual particle beams which pass through the final multi-aperture plate substantially also pass through the third multi-lens array,

wherein the controller is furthermore set up to supply an adjustable excitation to the particle lenses of the third multi-lens array.

In this case, it is possible that all lenses of the third multi-lens array experience the same excitation; however, it is also possible for the lenses of the multi-lens array to be excited differently on an individual basis. Only the components of the individual particle beams that are suitable or destined for particle-optical imaging pass through the final multi-aperture plate. Thus, the individual particle beams are geometrically shaped via the final multi-aperture plate. By contrast, the individual particle beams are focused via the third multi-lens array and, for example, imaged onto an intermediate image plane.

According to a further embodiment of the disclosure, the final beam-shaping system alternatively comprises the following:
a final multi-aperture plate with a multiplicity of openings, which is arranged in such a way that the individual particle beams are partly incident on the final multi-aperture plate and absorbed there and partly pass through the openings in the final multi-aperture plate;
a multi-lens plate with a multiplicity of openings, which is arranged in the beam path downstream of the final multi-aperture plate in such a way that the individual particle beams which pass through the final multi-aperture plate also pass through the multi-lens plate; and
at least one first aperture plate, which has a single opening and which is arranged in the beam path downstream of the multi-lens plate in such a way that the individual particle beams which pass through the multi-lens plate also pass through the opening in the at least first aperture plate; and
wherein the controller is furthermore set up to supply an adjustable excitation to the at least one first aperture plate. Two, three, four or more aperture plates can also be provided, and these are then each able to be supplied with an adjustable excitation by the controller.

The particle beam system in this case furthermore can comprise a second multi-deflector array, which is arranged in the beam path just upstream of the final multi-aperture plate, wherein the controller is furthermore set up to supply individually adjustable excitations to the second multi-deflector array and thus individually deflect the individual particle beams.

With the aid of this embodiment it is possible to influence the pitch between the individual particle beams in the intermediate image plane. Specifically, the design of the global electrostatic electrode(s) downstream the multi-lens plate renders it possible to generate negative field curvature in the intermediate image plane. The magnitude of this negative field curvature can be chosen in such a way that it exactly compensates a subsequently occurring (positive) field curvature during the particle-optical imaging from the intermediate image plane into the object plane. Thus, no further field curvature correction is involved any more in that case.

According to a further embodiment of the disclosure, the condenser lens system comprises one or more global condenser lenses, for example an electrostatic or magnetic double condenser. However, it is also possible for the condenser lens system to comprise a condenser lens array with a multiplicity of openings, through which the individual particle beams pass. Thus, the choice in respect of the condenser lens system is between a global lens system and a micro lens system.

According to an embodiment of the disclosure, the objective lens system comprises a global magnetic objective lens. What is true here is that all individual particle beams pass through the same (large) opening of the magnetic objective lens. However, alternatively it is also possible for the objective lens system to comprise an objective lens array with a multiplicity of openings, which is arranged in the beam path in such a way that the individual particle beams pass through the openings in the objective lens array. What is true in this case is that the objective lens array substantially represents an Einzel-lens array. Other embodiments are also possible. However, it is true in any case that the objective lens array, as an example of a micro lens array, is in turn producible using MEMS technology. The preceding field lens system has a focusing effect on the individual particle beams. This means that the individual particle beams form a cross over in the direction of the objective lens system. Optionally, this cross over is located upstream of the objective lens. If use is now made of an objective lens array and not a global magnetic objective lens, the cross over of the individual particle beams, which is otherwise desired in the particle-optical beam path, can also be dispensed with. This is desirable on account of the Coulomb effect. In this case, the objective lens array is arranged just upstream of the cross over of the individual particle beams otherwise present; however, this has as a consequence that the hole pitch in the objective lens array is significantly smaller than the pitch of the individual particle beams in the intermediate image plane. Consequently, no cross over of the individual particle beams can be provided between the field lens system and the object plane. For example, no cross over then is provided in the region of the objective lens system.

According to a further aspect of the disclosure, the latter relates to a multi-beam particle microscope with a particle beam system as described above in a plurality of embodiments. In this case, the multi-beam particle microscope can comprise a beam splitter in a manner known per se, in order to separate primary particle beams from secondary particle beams. Moreover, it can comprise a detection unit in a manner known per se, the latter facilitating a spatially resolved detection of secondary electron beams.

The embodiments described above with respect to the first and second aspect of the disclosure can be partly or fully combined with one another, as long as no technical contradictions occur.

### BRIEF DESCRIPTION OF THE DRAWINGS

The disclosure may be understood even better with reference to the accompanying figures. In the figures:

FIG. 1 shows a schematic illustration of a multi-beam particle microscope;

FIG. 2 shows a schematic illustration of a multi-source system according to the disclosure;

FIG. 3 shows a schematic illustration of a particle beam system comprising a multi-source system and further system components;

FIG. 4 shows a schematic illustration of a particle beam system comprising a multi-source system, an objective lens array and further system components;

FIG. 5 shows a particle beam system for correcting the direction of individual particle beams;

FIGS. 6A-6B shows magnetic field generation mechanism above a particle multi-source according to an example;

FIGS. 7A-7B shows magnetic field generation mechanism level with a particle multi-source according to an example; and

FIGS. 8A-8B shows magnetic field generation mechanism above a particle multi-source according to an example.

### DETAILED DESCRIPTION

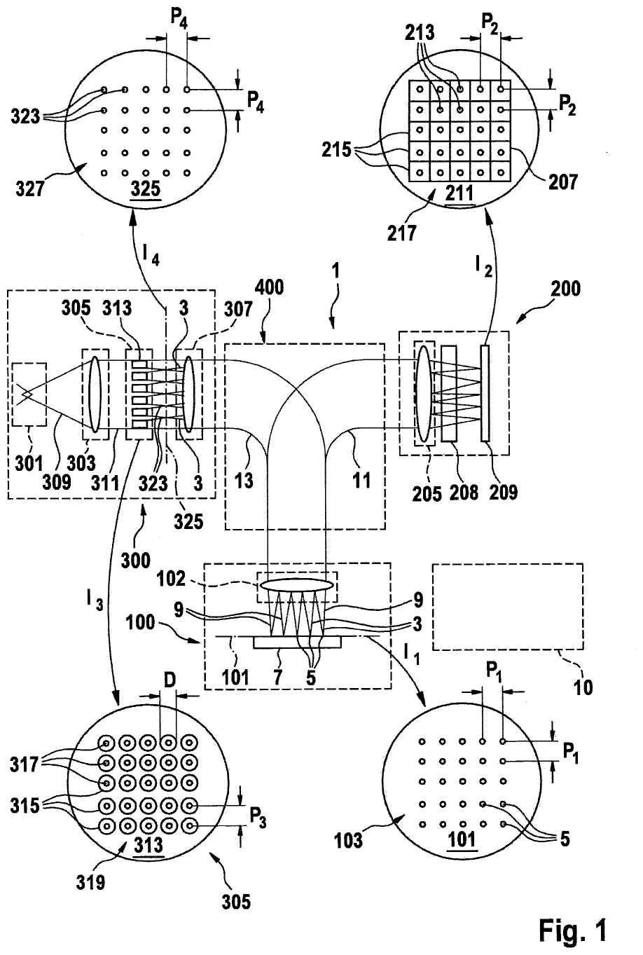

FIG. 1 is a schematic illustration of a particle beam system 1 in the form of a multi-beam particle microscope 1, which uses a multiplicity of particle beams. The particle beam system 1 generates a multiplicity of particle beams which strike an object to be examined in order to generate there interaction products, e.g. secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and generate there a plurality of electron beam spots, or spots, that are spatially separated from one another. The object 7 to be examined can be of any desired type, e.g. a semiconductor wafer or a biological sample, and comprise an arrangement of miniaturized elements or the like. The surface of the object 7 is arranged in a first plane 101 (object plane) of an objective lens 102 of an objective lens system 100.

The enlarged excerpt I₁ in FIG. 1 shows a plan view of the object plane 101 having a regular rectangular field 103 of locations of incidence 5 formed in the first plane 101. In FIG. 1, the number of locations of incidence is 25, which form a 5×5 field 103. The number 25 of locations of incidence is a number chosen for reasons of simplified illustration. In practice, the number of beams, and hence the number of locations of incidence, can be chosen to be significantly greater, such as, for example, 20×30, 100×100 and the like.

In the embodiment illustrated, the field 103 of locations of incidence 5 is a substantially regular rectangular field having a constant pitch P₁ between adjacent locations of incidence. Exemplary values of the pitch P₁ are 1 micrometre, 10 micrometres and 40 micrometres. However, it is also possible for the field 103 to have other symmetries, such as a hexagonal symmetry, for example.

A diameter of the beam spots shaped in the first plane 101 can be small. Exemplary values of the diameter are 1 nanometre, 5 nanometres, 10 nanometres, 100 nanometres and 200 nanometres. The focusing of the particle beams 3 for shaping the beam spots 5 is carried out by the objective lens system 100.

The primary particles striking the object generate interaction products, e.g., secondary electrons, back-scattered electrons or primary particles that have experienced a reversal of movement for other reasons, which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the multiplicity of secondary particle beams 9 to a detector system 200. The detector system 200 comprises a particle-optical unit with a projection lens 205 for directing the secondary particle beams 9 at a particle multi-detector 209.

The excerpt I₂ in FIG. 1 shows a plan view of the plane 211, in which individual detection regions of the particle multi-detector 209 on which the secondary particle beams 9 are incident at the locations 213 are located. The locations of incidence 213 lie in a field 217 with a regular pitch P₂ with respect to one another. Exemplary values of the pitch P₂ are 10 micrometres, 100 micrometres and 200 micrometres.

The primary particle beams 3 are generated in a beam generation apparatus 300 comprising at least one particle source 301 (e.g., an electron source), at least one collimation lens 303, a multi-aperture arrangement 305 and a field lens 307, or a field lens system made of a plurality of field lenses. The particle source 301 generates at least one diverging particle beam 309, which is collimated or at least substantially collimated by the at least one collimation lens 303 in order to shape a beam 311 which illuminates the multi-aperture arrangement 305.

The excerpt I₃ in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A pitch P₃ between the midpoints 317 of the apertures 315 can have exemplary values of 5 micrometres, 100 micrometres and 200 micrometres. The diameters D of the apertures 315 are smaller than the pitch P₃ between the midpoints of the apertures. Exemplary values of the diameters D are 0.2× P₃, 0.4× P₃ and 0.8× P₃.

Particles of the illuminating particle beam 311 pass through the apertures 315 and form particle beams 3. Particles of the illuminating beam 311 which strike the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometres, 100 nanometres and 1 micrometre.

The field lens 307 and the objective lens 102 provide a first imaging particle-optical unit for imaging the plane 325, in which the beam foci 323 are formed, onto the first plane 101 such that a field 103 of locations of incidence 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle-optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which in the full scope thereof is incorporated by reference in the present application.

The multiple particle beam system furthermore comprises a computer system 10 configured both for controlling the individual particle-optical components of the multiple particle beam system and for evaluating and analysing the signals obtained by the multi detector 209. In this case, the computer system 10 can be constructed from a plurality of individual computers or components. It can also contain the controller according to the disclosure.

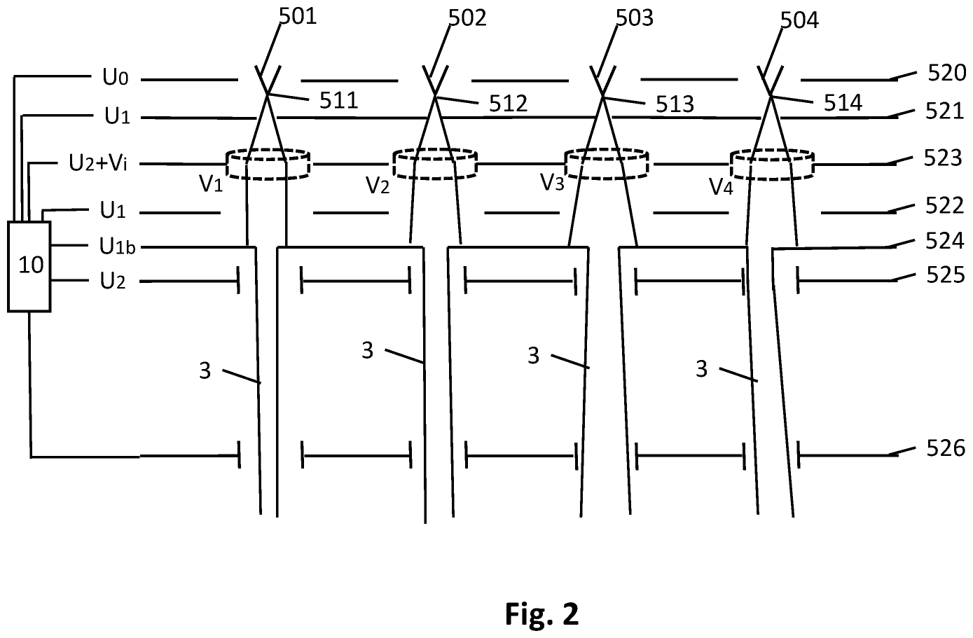

FIG. 2 shows a schematic illustration of a multi-source system 500 according to the disclosure. In this case, the multi-source system 500 comprises a particle multi-source, which is illustrated in the illustrated example by the particle sources 501, 502, 503 and 504. The particle multi-source is an electron emitter array, which was manufactured using MEMS technology. The emitted charged particles are electrons which are produced by field emission, for example. They form the individual particle beams 3. The individual particle beams 3 are pre-shaped in the multi-source system 500 since the luminance of the individual sources 501, 502, 503 and 504 can deviate from one another. Specifically, the beam current strength of the individual particle beams 3 is set via the multi-source system 500. Further (coarse or preliminary) beam shaping is also possible or illustrated schematically.

Specifically, the electrons leave the tips of the sources 501, 502, 503 and 504, the tips 511, 512, 513 and 514 being indicated by the tip of the “V”.

Following the emission, the individual particle beams 3 pass through the first multi-aperture plate 521, to which a voltage U₁ has been applied in the illustrated example. In this case, the first multi-aperture plate 521 serves as an extractor electrode. Here, the openings in the first multi-aperture plate 521 are chosen in such a way that the first aperture plate 521 blocks parts of the emitted individual particle beams.

A first multi-lens array 523 is arranged in the beam path downstream of the first multi-aperture plate 521. It has a multiplicity of individually adjustable particle lenses, which are indicated in FIG. 2 by the flat cylinders. By way of example, these can be ring electrodes. A voltage U₂+Vᵢ is applied to the first multi-lens array 523 in the example shown. In this case, the particle lenses of the first multi-lens array 523 can be controlled by way of the controller 10. The controller 10 is set up to supply an individually adjustable excitation to the particle lenses and thus individually adjust the focusing of the associated particle lens for each individual particle beam 3. A second multi-aperture plate 522 is arranged in the beam path downstream of the first multi-lens array 523. Substantially the voltage U₁ is applied thereto in turn in the example shown. Consequently, the first multi-aperture plate 521, the first multi-lens array 523 and the second multi-aperture plate 522 form a sequence of Einzel-lenses for the individual particle beams 3. Overall, a focusing effect on the individual particle beams arises.

The focusing effect on the individual particle beams differs depending on how big the voltage Vᵢ is chosen to be. They are focused differently or expanded to different extents. This is evident when the beam current-restricting multi-aperture plate 524, which is arranged downstream of the second multi-aperture plate 522 in the beam path, is considered. The openings in the beam current-restricting multi-aperture plate 524 are smaller in terms of diameter than the openings in the second multi-aperture plate 522 and in the first multi-lens array 523. In general all plates or arrays are arranged in such a way that their openings are located above one another in centred fashion. According to an alternative embodiment of the disclosure, the second multi-aperture plate 522 and the beam current-restricting multi-aperture plate 524 can also be functionally combined or brought together with one another.

In the example shown, the voltage V₁ is chosen in such a way that the associated lens is strongly excited or the individual particle beam 3 is strongly focused. In the process, it passes almost in full through the beam current-restricting multi-aperture plate 524. By contrast, the second and the fourth lens of the first multi-lens array 523 are less strongly excited and the individual particle beam 3 passing therethrough is expanded to a greater extent. As a consequence, a greater proportion of the associated individual particle beams 3 is blocked by the beam current-restricting multi-aperture plate 524. The third lens in the first multi-lens array 523 is strained the least and the associated individual particle beam 3 is expanded to the greatest possible extent. Accordingly, large parts of the individual particle beam 3 are blocked at the beam current-restricting multi-aperture plate 524 in this case. The voltages at the lenses in the first multi-lens array 523 can now be chosen in a targeted manner such that the beam current strength of the individual particle beams 3 is approximately the same following the passage through the beam-current restricting multi-aperture plate 524. In this way, the different luminance levels of the sources 501, 502, 503 and 504 can be corrected or can be pre-corrected for the subsequent particle-optical imaging. The following relationship can apply to deviations δ of the individual beam currents from an arithmetic mean of the beam currents immediately after the beam current-restricting multi-aperture plate 524 has been passed through: δ≤5%, such as δ≤2%, for example δ≤1%.

A multi-deflector array 525 is provided in the beam path below the beam current-restricting multi-aperture plate 524. This multi-deflector array can likewise be excited by the controller 10. Here, it is possible to apply a voltage U₂ in targeted and individual fashion to each opening in the array 525. The direction of the individual particle beams 3 can be corrected on the basis of the voltage applied and the direction of the electric field in the deflector. This can be relevant if the beam 3 is incident on the beam current-restricting multi-aperture plate 524 in a manner that is not exactly parallel to the optical axis Z (not illustrated here). This may be the case if the sequence of the plates is not exactly aligned; the precision when aligning the plates with respect to one another is limited in practice, for example leading to tilted beam axes. The correction function of the deflector of the multi-deflector array 525 is illustrated in exemplary fashion for the individual particle beam 3 far right, which originates from the source 504: In this case, the individual particle beam 3 is deflected significantly to the left.

Additionally, the multi-source system 500 comprises a multi-stigmator array 526 in the example shown.

All components of the multi-source system 500 can be controlled via the controller 10 in the example shown. In this case, the controller 10 can be identical to the overall controller of a multi-beam particle microscope 1. However, this could also be a separate controller 10.

Here, the dimensions of the multi-source system 500 are comparatively small in the direction of the optical axis Z (not plotted): In the illustrated example, the overall extent in the direction of the optical axis Z can be less than 20 mm.

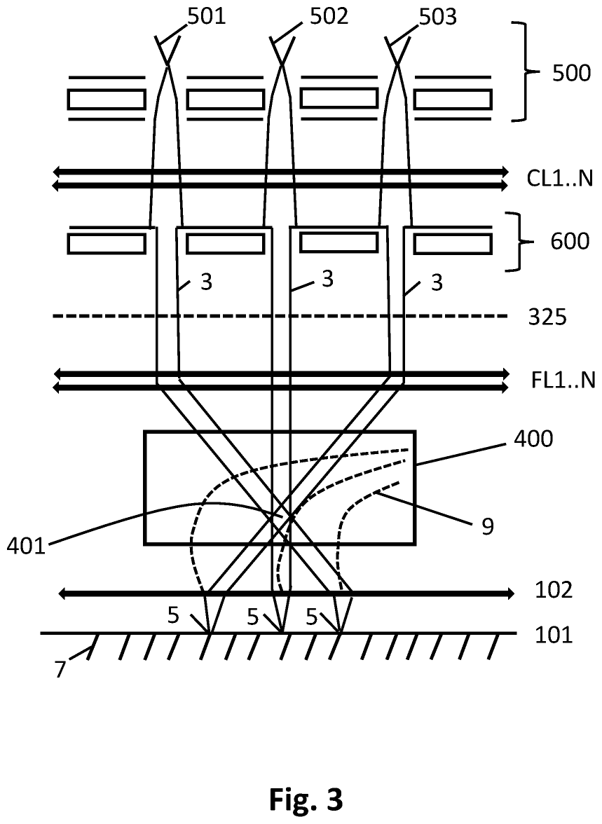

FIG. 3 shows a schematic illustration of a particle beam system 1 comprising a multi-source system 500 and further system components. The beam paths are presented in a much-simplified fashion. Specifically, FIG. 3 shows the integration of the multi-source system 500 according to the disclosure in already existing particle beam systems 1. A multiplicity of individual particle beams 3 are produced via the multi-source system 500 and the individual particle beams 3 are subjected to pre-shaping. For example, the different luminance levels of the sources 501, 502, 503 is compensated in the process. A condenser lens system CL1 . . . N is arranged in the beam path downstream of the multi-source system 500. For example, this can be a multiple condenser lens system. However, it would also be possible to replace the global condenser lenses CL1 . . . N with a condenser lens array.

The final beam-shaping system 600 is arranged in the beam path downstream of the condenser lens system CL1 . . . N. The latter is only presented in a schematic and much-simplified fashion. It comprises the final multi-aperture plate. However, it can also still comprise further particle-optical components, such as a third multi-lens array or a stigmator array, for example. It is generally desirable that the final beam shaping for the individual particle beams 3, which allows high quality imaging, is implemented via the final beam-shaping system 600. In this case, the individual particle beams are clipped via the final multi-aperture plate and only the centrally arranged individual particle beam constituent parts pass through the final multi-aperture plate. This allows elimination or compensation in the further beam path of aberrations which occurred in the multi-source system 500 during the beam shaping or which are yet to arise in the further beam path. After passing through the final beam-shaping system 600, the individual particle beams 3 are focused into the intermediate image plane 325. In view thereof, the illustration in FIG. 3 is likewise very much simplified in order to ensure an appropriate level of clarity. The individual particle beams 3 focused into the intermediate image plane 325 are then imaged into the object plane 101 by the subsequent particle-optical imaging. To this end, they initially pass through a field lens system FL1 . . . N, via which the individual particle beams 3 are focused. The individual particle beams 3 cross in the cross over 401 before they are focused by the global objective lens 102, a global magnetic objective lens 102 in this case, and are imaged on the sample 7 in the object plane 101 at locations of incidence 5. Secondary electron beams 9 emanate from the locations of incidence 5 and these are separated from the primary beams 3 via a beam switch 400. The detection system 200 with a particle multi-detector 209 is not shown in FIG. 3 for reasons of simplicity.

In summary, FIG. 3 shows the combination of the multi-source system 500 according to the disclosure and the final beam-shaping system 600 with global lens elements.

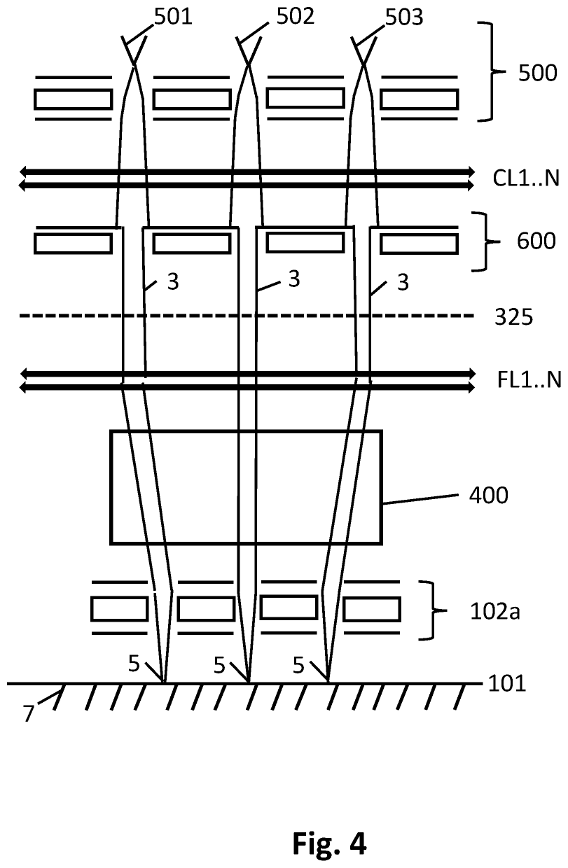

FIG. 4 shows a further schematic illustration of a particle beam system 1 comprising a multi-source system 500 and further system components. The beam paths are presented in a much-simplified fashion. The same reference signs in the figures label the same elements. Only the differences between FIGS. 3 and 4 are discussed in more detail below. Unlike in FIG. 3, FIG. 4 contains an objective lens array 102a. The latter is illustrated schematically and can be realized, for example, by way of an Einzel-lens array. Unlike in FIG. 3, the particle beam system 1 does not have a cross over 401. The objective lens array 102a is arranged so high up or so early in the beam path of the particles that the objective lens array 102a is arranged upstream of the (theoretical) cross over 401. Dispensing with the cross over 401 is desirable in view of the suppression of the Coulomb effect. Thus, overall, FIG. 4 shows a combination of the multi-source system 500 according to the disclosure and of the final beam-shaping system 600, both with global lens elements (condenser lens system CL1 . . . N and field lens system FL1 . . . N) and with a further micro lens system, which is present in the form of the objective lens array 102a. Here, the objective lens array 102a can have different configurations. By way of example, it can comprise a plurality of sequentially arranged multi-aperture plates, to which voltages are applied in suitable fashion and, for example, via the controller 10. In addition or as an alternative thereto, the objective lens array 102a can comprise a further multi-lens array. In the embodiment illustrated in FIG. 4, it is also possible to provide a detection unit with segmented detectors in the region of the objective lens array 102a in place of the beam switch 400 in combination with the projection path to the detection unit (the latter two are not illustrated).

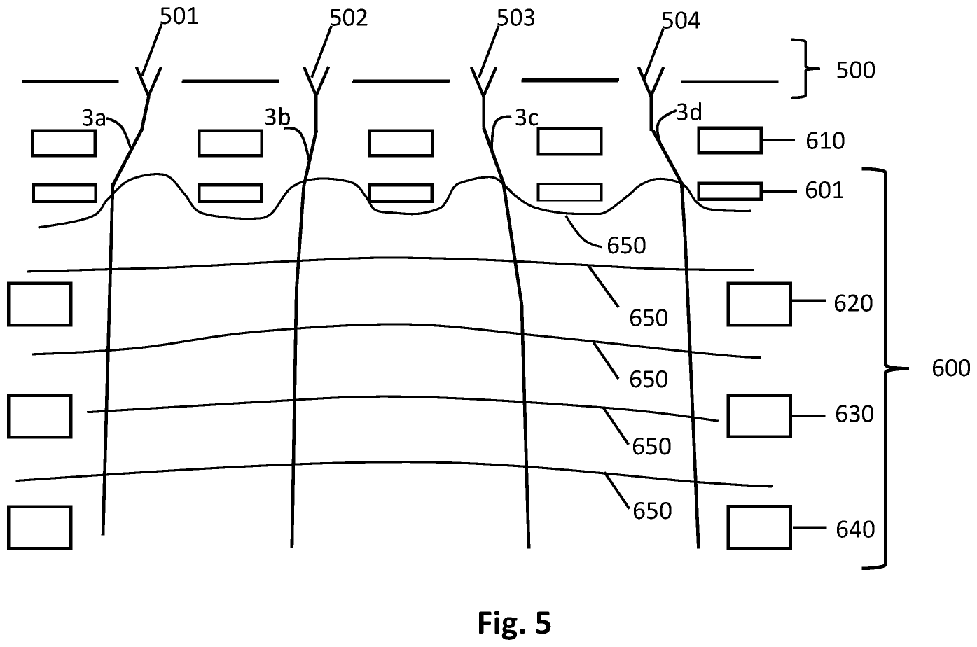

FIG. 5 shows a particle beam system 1 for correcting the direction of individual particle beams 3 in a schematic and much-simplified fashion. The multi-source system 500 with its sources 501, 502, 503 and 504 is illustrated in combination with the final beam-shaping system 600. The final beam-shaping system 600 comprises a final multi-lens plate 601, through which individual particle beams 3a, 3b, 3c and 3d pass. A final multi-aperture plate (not illustrated here) is arranged above the multi-lens plate 601. Moreover, the final beam-shaping system 600 comprises aperture plates 620, 630 and 640, it being possible to apply, e.g., global electric fields thereto. As a result, the electrostatic field can be shaped in targeted fashion in the region of the final beam-shaping system 600. As an alternative, it is also possible to use magnetic fields to this end.

Specifically, the electromagnetic fields also influence the extraction field close to the final multi-aperture plate: Depending on the application of voltages to the electrodes 620, 630, 640, the lens field in the multi-lens plate 601, and hence the focusing effect on the individual beams, can have different strengths. For example, suitable voltages at the electrodes 620-640 render it possible to let the lens field in the outer region (3a, 3d) have a weaker focusing effect on the individual particle beams than in the inner region (3b, 3c). Consequently, it is possible to compensate for a field curvature possibly present, the focal distribution of which in the image field having an opposite profile. However, the field distribution at the electrodes 620-640 also acts in size-reducing fashion on the intermediate image in this case; i.e., the beam pitch between the beams in the intermediate image plane becomes smaller. A multi-deflector array 610 arranged between the multi-source system 500 and the final beam-shaping system 600 contributes to correcting the beam pitch of the individual particle beams 3a, 3b, 3c and 3d in the intermediate image (not illustrated here). In the example shown, the individual particle beams 3a and 3b are each deflected to the left while the individual particle beams 3c and 3d are deflected to the right by way of an appropriate control of the deflectors in the multi-deflector array 610. With the aid of this embodiment it is possible to influence the pitch between the individual particle beams 3 in the intermediate image plane. Specifically, it is possible to produce negative field curvature in the intermediate image plane. The magnitude of this negative field curvature can be chosen in such a way that it exactly compensates a subsequently occurring (positive) field curvature during the particle-optical imaging from the intermediate image plane into the object plane. Thus, no further field curvature correction is involved any more in that case.

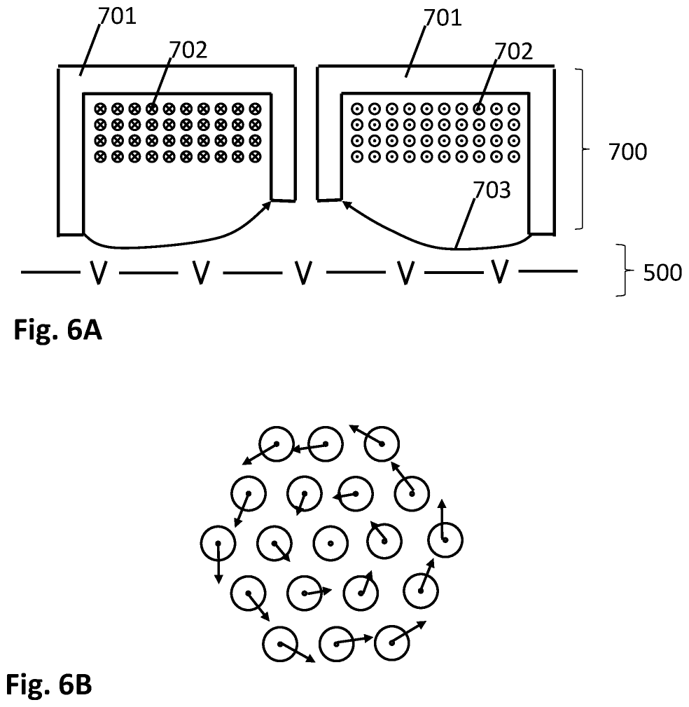

Generating a magnetic field in the region of the particle multi-source allows a generalized angular momentum to be impressed in a targeted manner on the emitted particles or electrons, the generalized angular momentum contributing overall to a telecentric incidence of the individual particle beams in the object plane 101 after passing through the particle beam system. It is possible to compensate a Larmor rotation caused by the magnetic immersion in the region of the objective lens. In this respect, FIGS. 6 to 8 show a few examples:

FIG. 6A shows magnetic field generation mechanism 700 for generating a divergent magnetic field. To this end, a multiplicity of coil windings 702 are provided in a pole shoe 701 with a rotationally symmetric embodiment about the optical axis Z. The magnetic field B is oriented as per reference sign 703. Projected onto the emitter plane of the multi-source system 500, the magnetic field B has a component perpendicular to the optical axis Z. At right angles to this radial direction, emitted electrons experience a corresponding start angle distribution. A start velocity vector projected onto the emitter plane is illustrated schematically in FIG. 6B using the arrows.

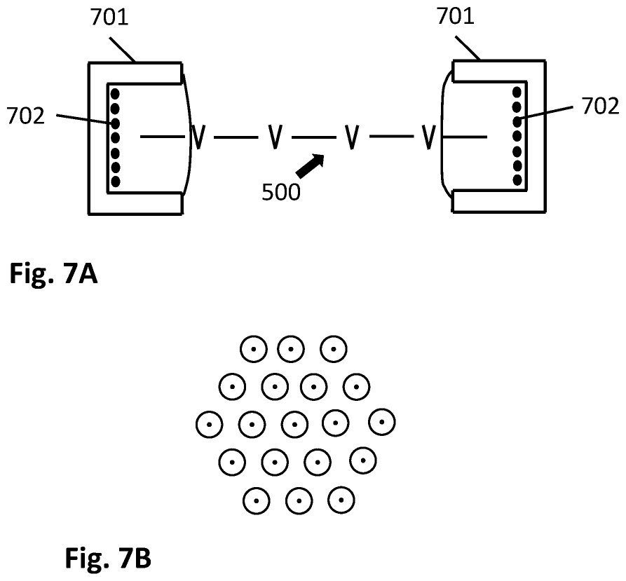

FIG. 7A shows magnetic field generation mechanism for generating a homogeneous magnetic field. This magnetic field has substantially no orthogonal component to the start direction of the emitted electrons. A corresponding start angle distribution is therefore punctual or not present (cf. FIG. 7B).

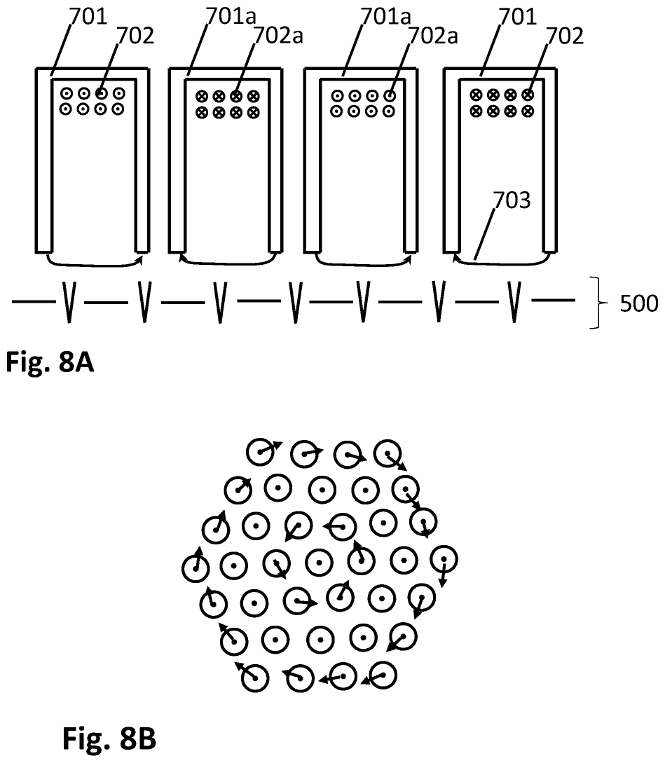

FIG. 8A shows a further example for shaping the magnetic field in order to impress onto the emitted electrons a dedicated start angle distribution in the magnetic field. Two concentric pole shoes 701 and 701a are illustrated; they each comprise a multiplicity of coil windings 702 and 702a, respectively. The direction of the magnetic field lines is indicated by 703. They are oriented in opposite directions between the two pole pots 701 and 701a. Accordingly, this also yields a start angle distribution running in opposite directions for the emitted electrons (cf. FIG. 8B).

In very general terms, the provision of a magnetic field impressed in a certain manner renders it possible to influence the start angle distribution for the electrons in a targeted fashion during the emission from the multi-sources in order to subsequently ensure telecentric conditions in the particle beam system 1 upon incidence on an object 7. This facilitates, for example, a good inspection of HAR structures.

### LIST OF REFERENCE SIGNS

1 Multi-beam particle microscope
3 Primary particle beams (individual particle beams)
5 Beam spots, locations of incidence
7 Object
9 Secondary particle beams
10 Computer system, controller
100 Objective lens system
101 Object plane
102 Objective lens
102a Objective lens array
103 Field
200 Detector system
205 Projection lens
209 Particle multi-detector
211 Detection plane
213 Locations of incidence
217 Field
300 Beam generation apparatus
301 Particle source
303 Condenser lens system
305 Multi-aperture arrangement
313 Multi-aperture plate
315 Openings in the multi-aperture plate
317 Midpoints of the openings
319 Field
307 Field lens system
309 Diverging particle beam
311 Illuminating particle beam
323 Beam foci
325 Intermediate image plane
400 Beam switch
401 Cross over
500 Multi-source system
501 First particle source
502 Second particle source
503 Third particle source
504 Fourth particle source
511 First tip
512 Second tip
513 Third tip
514 Fourth tip
520 Suppressor electrode
521 First multi-aperture plate, extractor
522 Second multi-aperture plate, counter electrode
523 First multi-lens array
524 Beam current-restricting multi-aperture plate
525 Multi-deflector array
526 Multi-stigmator array
600 Final beam-shaping system
601 Multi-lens plate
602 Third multi-lens array
610 Multi-deflector array
620 Aperture plate
630 Aperture plate
640 Aperture plate
650 Electric field lines
700 Magnetic field generation mechanism
701 Pole shoe
702 Coil
703 Magnetic field
Z Optical axis

What is claimed is:

1. A particle beam system, comprising:
a multi-source system, comprising:
a particle multi-source configured to generate a multiplicity of charged individual particle beams via field emission;
a first multi-aperture plate comprising a multiplicity of first openings configured to have the charged individual particle beams at least partly pass therethrough;
a first multi-lens array comprising a multiplicity of individually adjustable particle lenses, the first multi-lens array downstream of the first multi-aperture plate along a beam path of charged individual particle beams so that the charged individual particle beams which pass through the first multi-aperture plate also pass through the first multi-lens array;
a second multi-aperture plate comprising a multiplicity of second openings, the second multi-aperture plate downstream of the first multi-lens array along the beam path of charged individual particle beams so that the charged individual particle beams which pass through the first multi-lens array also pass through the second multi-aperture plate;
a beam current-restricting multi-aperture plate comprising a multiplicity of beam current-restricting openings, the beam current-restricting multi-aperture plate downstream of the second multi-aperture plate along the beam path of charged individual particle beams so that the charged individual particle beams are partly incident on the beam current-restricting multi-aperture plate and absorbed there and partly pass through the openings in the beam current-restricting multi-aperture plate; and
a controller configured to supply an individually adjustable voltage to the particle lenses of the first multi-lens array to individually adjust a focusing of the associated particle lens for each individual particle beam.

2. The particle beam system of claim 1, further comprising a beam-shaping system downstream of the multi-source system along the beam path of charged individual particle beams, wherein the beam-shaping system is configured to provide a final shape of the charged individual particle beams for subsequent optical imaging.

3. The particle beam system of claim 2, further comprising:
a condenser lens system downstream of the multi-source system along the beam path of charged individual particle beams and upstream of the final beam-shaping system along the beam path of charged individual particle beams;
a field lens system downstream of the final beam-shaping system along the beam path of charged individual particle beams; and
an objective lens system downstream of the field lens system along the beam path of charged individual particle beams,
wherein the particle beam system is configured to form an intermediate image plane between the beam-shaping system and the field lens system.

4. The particle beam system of claim 3, wherein the beam-shaping system comprises:
a multi-aperture plate comprising a multiplicity of openings, the multi-aperture plate configured so that the charged individual particle beams are partly incident on the multi-aperture plate and absorbed there and partly pass through the openings in the multi-aperture plate; and
a second multi-lens array comprising a multiplicity of adjustable particle lenses, the second multi-lens array arranged along the beam path of charged individual particle beams downstream of the multi-aperture plate so that the charged individual particle beams which pass through the multi-aperture plate substantially also pass through the second multi-lens array.

5. The particle beam system of claim 3, wherein the condenser lens system comprises condenser lenses.

6. The particle beam system of claim 3, wherein the condenser lens system comprises a condenser lens array which comprises a multiplicity of openings configured to have the charged individual particle beams pass therethrough.

7. The particle beam system of claim 3, wherein the objective lens system comprises a global magnetic objective lens.

8. The particle beam system of claim 3, wherein the objective lens system comprises an objective lens array which comprises a multiplicity of openings, the objective lens along the beam path of charged individual particle beam to have the charged individual particle beams pass through the openings in the objective lens array.

9. The particle beam system of claim 8, wherein the particle beam system is configured so that no cross over of the charged individual particle beams is provided between the field lens system and the object plane.

10. The particle beam system of claim 2, wherein the beam-shaping system comprises:
a multi-aperture plate with a multiplicity of openings, the multi-aperture plate configured so that the charged individual particle beams are partly incident on the multi-aperture plate and absorbed there and partly pass through the openings in the multi-aperture plate;
a multi-lens plate comprising a multiplicity of openings, the multi-lens plate downstream of the multi-aperture plate along the beam path of charged individual particle beams so that the charged individual particle beams which pass through the multi-aperture plate also pass through the multi-lens plate; and
a first aperture plate comprising a single opening, the first aperture plate downstream of the multi-lens plate along the beam path of charged individual particle beams so that charged individual particle beams which pass through the multi-lens plate also pass through the opening in the at least first aperture plate,
wherein the controller is configured to supply an adjustable excitation to the first aperture plate.

11. The particle beam system of claim 10, further comprising a second multi-deflector array upstream of the multi-aperture plate along the beam path of charged individual particle beams, wherein the controller is configured to supply individually adjustable excitations to the second multi-deflector array to individually deflect the charged individual particle beams.

12. The particle beam system of claim 2, wherein a deviation 6 of the individual beam currents from an arithmetic mean of the beam currents immediately after the beam current-restricting multi-aperture plate has been passed through is less than or equal to 5%.

13. The particle beam system of claim 1, wherein at least one of the following holds:
the first multi-aperture plate comprises an extractor electrode;
the second multi-aperture plate comprises a counter electrode; and
the beam current-restricting multi-aperture plate comprises an anode.

14. The particle beam system of claim 1, wherein the particle beam system is configured to have an identical first voltage applied to the first multi-aperture plate and the second multi-aperture plate, and wherein the individually adjustable voltages at the first multi-lens array differ from the first voltage.

15. The particle beam system of claim 1, wherein a distance between the particle multi-source and the beam current-restricting multi-aperture plate is greater than or equal to 0.1 mm and less than or equal to 30 mm.

16. The particle beam system of claim 1, wherein the multi-source system further comprises a suppressor electrode.

17. The particle beam system of claim 1, wherein:
the multi-source system comprises a second multi-lens array which comprises a multiplicity of individually adjustable and focusing particle lenses;
the second multi-lens array is downstream of the beam current-restricting multi-aperture plate along the beam path of charged individual particle beams so that the particles of the charged individual particle beams which pass through the beam current-restricting multi-aperture plate substantially also pass through the second multi-lens array; and
the controller is configured to supply an individually adjustable voltage to the particle lenses of the second multi-lens array to individually set a focusing of the associated particle lens for each individual particle beam.

18. The particle beam system of claim 1, wherein:
the multi-source system further comprises a first multi-deflector array configured to have the charged individual particle beams pass therethrough;
the multi-source array is downstream of the beam current-restricting multi-aperture plate along the beam path of charged individual particle beams; and
the controller is configured to supply individually adjustable excitations to the first multi-deflector array to individually deflect the charged individual particle beams.

19. The particle beam system of claim 1, wherein:
the multi-source system further comprises a multi-stigmator array configured to have the charged individual particle beams pass therethrough; and
the controller is configured to supply an adjustable excitation to the multi-stigmator array.

20. The particle beam system of claim 1, wherein the multi-source system is manufactured at least in part via MEMS technology.

21. The particle beam system of claim 1, wherein the particle multi-source comprises at least one member selected from the group consisting of metallic emitters, silicon-based emitters, and carbon nanotubes-based emitters.

22. The particle beam system of claim 1, further comprising a magnetic field generation mechanism configured so that the particle multi-source is in a magnetic field generated by the magnetic field generation mechanism.

23. The particle beam system of claim 22, wherein the magnetic field generated by the magnetic field generation mechanism has a component perpendicular and/or a component parallel to an emission direction of the charged particles from the multi-source.

24. The particle beam system of claim 22, wherein the magnetic field generation mechanism is configured so that a start angular distribution of the charged particles caused by the magnetic field following the emergence of the charged particles from the particle source depends on the radial distance between the respective particle source and the optical axis of the particle beam system.

25. A multi-beam particle microscope, comprising:
a particle beam system according to claim 1.
